(19) United States
(12) Patent Application Publication
(10) Pub. No.: US 2015/0256180 A1
(43) Pub. Date: Sep. 10, 2015

(54) FIELD PROGRAMMABLE GATE ARRAY AND SWITCH STRUCTURE THEREOF

(71) Applicant: Shanghai Huahong Grace Semiconductor Manufacturing Corporation, Shanghai (CN)

(72) Inventor: Jun XIAO, Shanghai (CN)

(73) Assignee: Shanghai Huahong Grace Semiconductor Manufacturing Corporation, Shanghai (CN)

(21) Appl. No.: 14/581,114

(22) Filed: Dec. 23, 2014

(30) Foreign Application Priority Data
Mar. 10, 2014 (CN) 201410086089.8

(51) Int. Cl. H03K 19/177

(52) U.S. Cl. CPC H03K 19/1776

(57) ABSTRACT

A field programmable gate array and a switch structure thereof are provided by the present disclosure. The field programmable gate array, including: a split gate memory; a programmable logic unit; and a wiring structure of the programmable logic unit; wherein the wiring structure includes interconnection nodes located on connection points thereof, and the split gate memory is adapted to provide an interconnection relation between the interconnect nodes. In the present disclosure, a switch structure of the field programmable gate array is able to be integrated with a memory thereof. Therefore, the field programmable gate array may have low cost and high reliability.

### CROSS-REFERENCE TO RELATED APPLICATIONS

The present application claims priority to Chinese patent application No. 201410086089.8, filed on Mar. 10, 2014, and entitled “FIELD PROGRAMMABLE GATE ARRAY AND SWITCH STRUCTURE THEREOF”, the entire disclosure of which is incorporated herein by reference.

### TECHNICAL FIELD

The present disclosure generally relates to integrated circuits (IC), and more particularly, to a field programmable gate array and a switch structure of the field programmable gate array.

### BACKGROUND

Field programmable gate array (FPGA) integrated circuits (IC) have seen rapid development recently. There are two types of FPGA, one is one-time programmable (OTP) FPGA, and the other one is programmable FPGA. In the OTP FPGA, components such as anti-fuses can be used for establishing programmable connections. In the programmable FPGA, transistor switches are used for establishing programmable connections.

Generally, a FPGA includes a logic element array and an interconnection wiring having thousands of programmable interconnection cells, so that the FPGA can be integrated into an IC for achieving desired functions. Each programmable interconnection cell or each switch is adapted to couple two circuit nodes in the IC, for controlling the interconnection wiring to be connected or disconnected, or for achieving one or more functions of the logic element.

The FPGA further includes a memory which is adapted to store program information for controlling the programmable interconnection cells. The memory may be a non-volatile memory such as an electrically programmable read-only-memory (EPROM), an electrically erasable programmable read-only memory (EEPROM), a non-volatile random-access memory (RAMs) or a flash memory.

Nowadays, manufacturing processes of the non-volatile memories have been improved gradually, so that some of the non-volatile memories can have optimal densities, can be programmed or reprogrammed easily, and can be read immediately. Further, these non-volatile memories can have low cost, high densities, reduced power consumptions and high reliabilities. However, the switch of the FPGA still has some drawbacks.

### SUMMARY

According to one embodiment of the present disclosure, a FPGA is provided, including: a split gate memory, a programmable logic unit, and a wiring structure of the programmable logic unit; wherein the wiring structure includes interconnection nodes located on connection points thereof, and the split gate memory is adapted to provide an interconnection relation between the interconnection nodes.

In some embodiments, the split gate memory includes: a first split gate storage array adapted to store content implemented by the programmable logic unit; and a second split gate storage array adapted to connect the interconnection nodes.

In some embodiments, the interconnection nodes include a first interconnection node and a second interconnection node interconnected with each other, where the second split gate storage array includes a first split gate storage bit and a second split gate storage bit each of which includes a bit line electrode, a control gate and a source line electrode; the bit line electrode of the first split gate storage bit is coupled to the first interconnection node, the control gate of the first split gate storage bit is coupled to a gate control voltage, and the source line electrode of the first split gate storage bit is adapted to be coupled to a programming voltage when the first interconnection node and the second interconnection node are interconnected; and the bit line electrode of the second split gate storage bit is coupled to the second interconnection node, the control gate of the second split gate storage bit is coupled to the gate control voltage, and the source line electrode of the second split gate storage bit is adapted to be coupled to the programming voltage when the first interconnection node and the second interconnection node are interconnected.

Optionally, the first split gate storage bit and the second split gate storage bit use a common source line electrode.

Optionally, the FPGA further includes a control transistor which has one end coupled to a control voltage, another end coupled to the source line electrodes of the first split gate storage bit and the second split gate storage bit, and a control end coupled to an enable signal; wherein the enable signal works when the first interconnection node and the second interconnection node are interconnected.

According to one embodiment of the present disclosure, a switch structure for a FPGA is also provided, wherein the FPGA includes a programmable logic unit and a wiring structure having interconnection nodes at connection points thereof. The switch structure includes a split gate memory coupled between the interconnection nodes.

Optionally, the split gate memory of the switch structure includes: a first split gate storage array adapted to store an implementation of the programmable logic unit, and a second split gate storage array adapted to connect the interconnection nodes.

Optionally, the interconnection nodes of the switch structure include a first interconnection node and a second interconnection node having the interconnection relation with each other, where the second split gate storage array includes a first split gate storage bit and a second split gate storage bit either of which includes a bit line electrode, a control gate and a source line electrode; the bit line electrode of the first split gate storage bit is coupled to the first interconnection node, the control gate of the first split gate storage bit is coupled to a gate-control voltage, and the source line electrode of the first split gate storage bit is adapted to be coupled to a programming voltage when the first interconnection node and the second interconnection node are interconnected; and the bit line electrode of the second split gate storage bit is coupled to the second interconnection node, the control gate of the second split gate storage bit is coupled to the gate-control voltage, and the source line electrode of the second split gate storage bit is adapted to be coupled to the programming voltage when the first interconnection node and the second interconnection node are interconnected.

Optionally, in the switch structure, the first split gate storage bit and the second split gate storage bit use a common source line electrode.

The FPGA provided by the present disclosure has follow advantages.

In a FPGA provided by the present disclosure, the switch structure and the component which stores program information for controlling the programmable logic unit are implemented by a same memory. Thus, the switch structure and the memory of the FPGA can be fabricated in a same process. Therefore, both the manufacturing process and the structure of the FPGA can be simplified. The producing cost can be reduced and the producing efficiency can be improved.

The component which is stored with program information for controlling the programmable logic unit can be formed by a technological process for forming a flash memory. Thus, the component being formed may have high speed structure, low cost, high density, low power consumption and high reliability. Furthermore, in the present disclosure, a fraction of the flash memory can serve as the switch structure of the FPGA. Accordingly, the switch structure and the memory can be integrated together through a high quality technological process. Therefore, the switch structure of the FPGA may have low cost, high density, low power consumption and high reliability as well.

In the technical solution provided by the present disclosure, a connection or a disconnection between the interconnection nodes of the wiring structure of the FPGA is controlled by a connection or a disconnection of the corresponding storage bit of the split gate memory, respectively. Further, the connection or disconnection between the interconnection nodes can be directly recorded by the split gate memory which serves as a switch structure as well, thus the connection or disconnection can be directly programmed, erased and read. Therefore, a FPGA having integral structure and high working efficiency may be obtained.

### BRIEF DESCRIPTION OF THE DRAWINGS

FIG. 1 schematically illustrates a structure of an FPAG according to one embodiment of the present disclosure;

FIG. 2 schematically illustrates a structure of a split gate memory according to one embodiment of the present disclosure;

FIG. 3 schematically illustrates switch structures of two interconnection nodes having an interconnection relation according to one embodiment of the present disclosure; and

FIG. 4 schematically illustrates switch structures of multiple interconnection nodes having an interconnection relation according to one embodiment of the present disclosure.

### DETAILED DESCRIPTION

In order to clarify the objects, characteristics and advantages of the present disclosure, embodiments of the present disclosure will be described in detail in conjunction with the accompanying drawings. The disclosure will be described with reference to certain embodiments. Accordingly, the present disclosure is not limited to the embodiments disclosed. It will be understood by those skilled in the art that various changes may be made without departing from the spirit or scope of the disclosure.

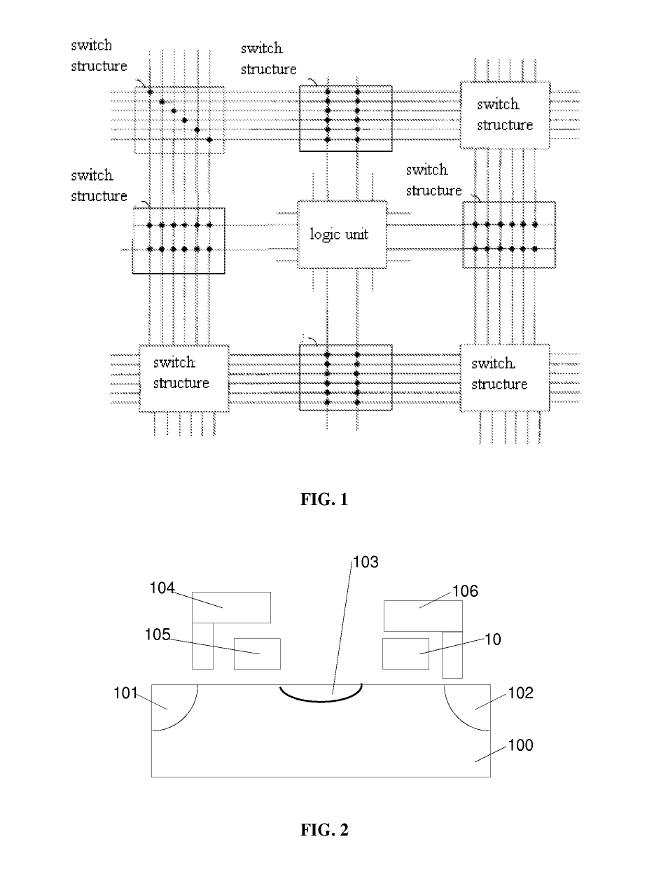

A filed programmable gate array (FPGA) may include a plurality of programmable logic units, input-output units and wiring resources. As shown in FIG. 1, configuration of a logic unit and a switch structure around the logic unit is illustrated. The switch structure includes a plurality of switch elements which are disposed all over wirings of the logic unit. The switch elements can provide universal interconnections for sub-wirings of the entire device.

According to length of the wirings, it can be classified into four different categories which are single-length wirings, double-length wirings, sixfold-length wirings and long-term wirings. A number of grids and interconnection nodes which are located on the grids are formed by crisscross wirings. As shown in FIG. 1, the interconnection nodes are indicated by solid dots. Furthermore, an opened state or a closed state between the interconnection nodes is controlled by corresponding switch element on the interconnection nodes. Assembly of the switch elements is defined as the switch structure.

In the present disclosure, the FPGA includes a split gate memory which serves both as a component for storing content implemented by the programmable logic unit and as the switch structure. Specifically, the interconnection nodes as shown in FIG. 1 include a first interconnection node and a second interconnection node having an interconnection relation with each other. The first interconnection node and the second interconnection node are configured to have the switch elements, wherein each of switch elements at least includes one split gate storage bit of the split gate memory.

Referring to FIG. 2, a cross sectional structure of a split gate storage unit is illustrated. The split gate storage unit includes: a substrate 100, an intermediate electrode 103, a first storage bit and a second storage bit being symmetrically disposed on two sides of the intermediate electrode 103. The first storage bit includes a drain 101, a first control gate 104 and a first floating gate 105; the second storage bit includes a source 102, a second control gate 106 and a second floating gate 107. The drain 101 and the source 102 are located inside the substrate 100, and the first control gate 104, the first floating gate 105, the second control gate 106, and the second floating gate 107 are located above the substrate 100. When the storage unit illustrated in FIG. 2 serves as the switch element of one of the interconnection nodes, one of the first storage bit and the second storage bit is able to be used for storing connection or disconnection information of one of the interconnection nodes, while the other one first storage bit and the second storage bit is able to be used for storing connection or disconnection information of the other interconnection nodes.

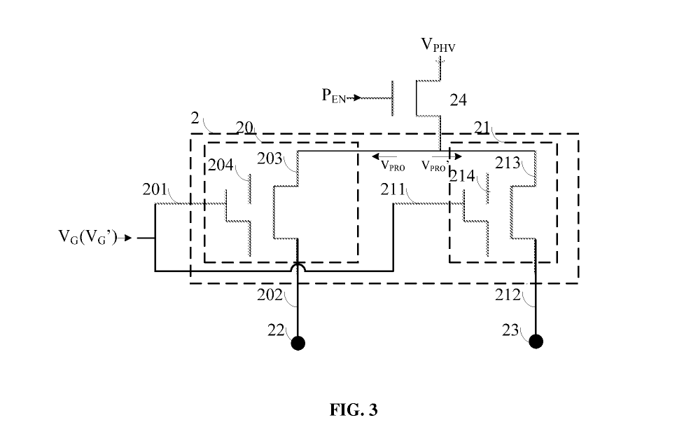

As shown in FIG. 3, the switch structures of two interconnection nodes having an interconnection relation can be configured to a split gate storage unit. Specifically, the split gate storage unit 2 has a first storage bit 20 and a second storage bit 21. The first storage bit 20 corresponds to a first interconnection node 22, the second storage bit 21 corresponds to a second interconnection node 23, and the first interconnection node 22 and the second interconnection node 23 have the interconnection relation with each other.

Regarding to the first interconnection node 22, connection or disconnection information of the first interconnection node 22 is stored by the first storage bit 20. Specifically, the control gate 201 of the first storage bit 20 is controlled by a gate voltage V_{G}, the drain 202 of the first storage bit 20 is coupled to the first interconnection node 22, the source 203 of the first storage bit 20 is coupled to a programming voltage V_{PRO}. By default, the first storage bit 20 stores the disconnection information of the first interconnection node 22 therein, and the first interconnection node 22 is in a disconnected state. In addition, changers are accumulated on the floating gate 204 of the first storage bit 20 at this time. When the gate voltage V_{G} is set to be a high electrical potential, for example 2.5 volt, and the programming voltage V_{PRO} is set to be a low electrical potential or a zero electrical potential, the changers accumulated on the floating gate 204 are able to be transferred and erased, thus the first interconnection node 22 is recorded as in a connected state. When the gate voltage V_{G} is reset to be a low electrical potential, for example 0.5 volt, and the programming voltage V_{PRO} is reset to be a high electrical potential, loading a drop-down current (may be about 3.5 mA) to the first interconnection node 22, so that the changers on the floating gate 204 can be regained for rewriting data into the first storage bit 20. Accordingly, the first interconnection node 22 is recorded as in the disconnected state again.

Similarly, regarding to the second interconnection node 23, connection or disconnection information of the second interconnection node 23 is stored by the second storage bit 21. Specifically, the control gate 211 of the second storage bit 21 is controlled by a gate voltage V_{G}′, the drain 212 of the second storage bit 21 is coupled to the second interconnection node 23, the source 213 of the second storage bit 21 is coupled to a programming voltage V_{PRO}′. By default, the second storage bit 21 stores the disconnection information of the second interconnection node 23 therein, and the second interconnection node 23 is in a disconnected state. In addition, changers are accumulated on the floating gate 214 of the second storage bit 21 at this time. When the gate voltage V_{G}′ is set to be a high electrical potential, for example 2.5 volt, and the programming voltage V_{PRO}′ is set to be a low electrical potential or a zero electrical potential, the changers accumulated on the floating gate 214 are able to be transferred and erased, thus the second interconnection node 23 is recorded as in a connected state. When the gate voltage V_{G}′ is reset to be a low electrical potential, for example 0.5 volt, and the programming voltage V_{PRO}′ is reset to be a high electrical potential, loading a drop-down current (may be about 3.5 mA) to the second interconnection node 23, so that the changers on the floating gate 214 can be regained for rewriting data into the second storage bit 21. Accordingly, the second interconnection node 23 is recorded as in the disconnected state again.

As the first interconnection node 22 and the second interconnection node 23 have the interconnection relation with each other, connection information and disconnection information of the first interconnect node 22 and the second interconnect node 23 are consistent with each other. Therefore, the gate voltage V_{G} and the gate voltage V_{G}′ are a same control signal, and the programming voltage V_{PRO} and the programming voltage V_{PRO}′ are a same control signal as well.

Referring still to FIG. 3, in the split gate storage unit 2, the first storage bit 20 and the second storage bit 21 share the source 203/213, thus the programming voltage V_{PRO} (or V_{PRO}′) can be controlled by a transistor 24. The transistor 24 may be a PMOS (P Metal Oxide Semiconductor) transistor, which has a source coupled to a programming high voltage V_{PHV}, a drain coupled to the shared source 203/213 of the first storage bit 20 and the second storage bit 21, and a gate coupled to a programming control signal P_{EN}. The programming control signal P_{EN} is in a high level when a programming (for example writing in the charges on the floating gate) is implemented to the storage bit. Otherwise, the programming control signal P_{EN} is in a low level.

In some embodiments, the first interconnection node 22 and the second interconnection node 23 do not have the interconnection relation with each other. Accordingly, the storage bit corresponding to the first interconnection node 22 and the storage bit corresponding to the second interconnection node 23 do not belong to a same storage unit, and receive different gate-control voltages and separate programming voltages, respectively.

In the FPGA, a number of switch structures may be provided for multiple (three or more) interconnection nodes. Configurations of the switch structures can be implemented through multiple split gate storage units or a storage unit array.

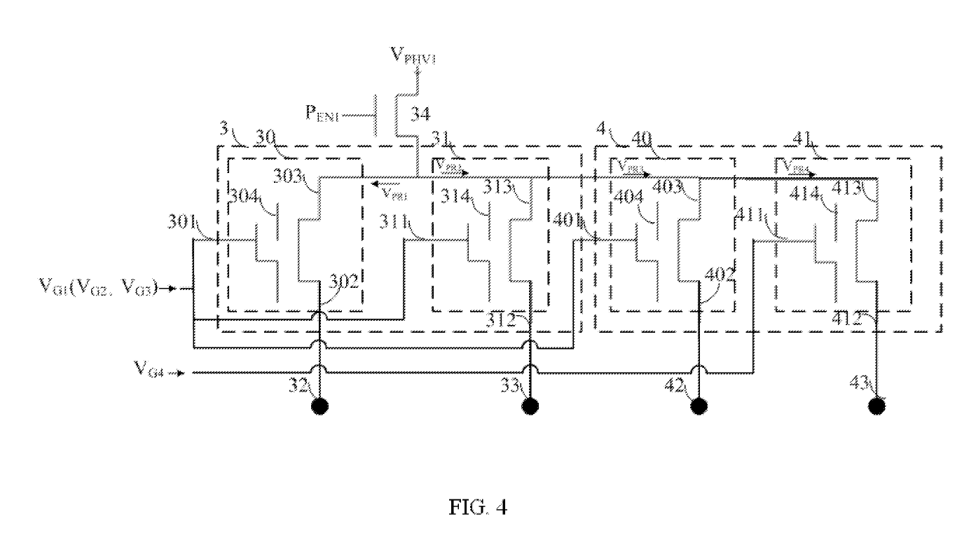

Referring to FIG. 4, three interconnection nodes having an interconnection relation are illustrated. Switch structures of the three interconnection nodes are correlated. Specifically, there are two split gate storage units which are respectively a split gate storage unit 3 and a split gate storage unit 4. The split gate storage unit 3 has a first storage bit 30 and a second storage bit 3, and the split gate storage unit 4 has a first storage bit 40 and a second storage bit 41. The first storage bit 30 and the second storage bit 31 of the split gate storage unit 3 correspond to the first interconnection node 32 and the second interconnection node 33, respectively. The first storage bit 40 and the second storage bit 41 of the split gate storage unit 4 correspond to the third interconnection node 42 and the fourth interconnection node 43, respectively. The first interconnection node 32, the second interconnection node 33 and the third interconnection node 42 have the interconnection relation, while the fourth interconnection node 43 does not have an interconnection relation with any one of the above three interconnection nodes.

Regarding to the first interconnection node 32, connection or disconnection information of the first interconnection node 32 is stored by the first storage bit 30. Specifically, the control gate 301 of the first storage bit 30 is controlled by a gate voltage V_{G1}, the drain 302 of the first storage bit 30 is coupled to the first interconnection node 32, and the source 303 of the first storage bit 30 is coupled to a programming voltage V_{PR1}. By default, the first storage bit 30 stores the disconnection information of the first interconnection node 32 therein, and the first interconnection node 32 is in a disconnected state. In addition, changers are accumulated on the floating gate 304 of the first storage bit 30 at this time. When the gate voltage V_{G1} is set to be a high electrical potential, for example 2.5 volt, and the programming voltage V_{PR1} is set to be a low electrical potential or a zero electrical potential, the changers accumulated on the floating gate 304 are able to be transferred and erased, thus the first interconnection node 32 is recorded as in a connected state. When the gate voltage V_{G1} is reset to be a low electrical potential, for example 0.5 volt, and the programming voltage V_{PR1} is reset to be a high electrical potential, loading a drop-down current (may be about 3.5 mA) to the first interconnection node 32, so that the changers on the floating gate 304 can be regained for rewriting data into the first storage bit 30. Accordingly, the first interconnection node 32 is recorded as in the disconnected state again.

Regarding to the second interconnection node 33, connection or disconnection information of the second interconnect node 33 is stored by the second storage bit 31. Specifically, the control gate 311 of the second storage bit 31 is controlled by a gate voltage V_{G2}, the drain 312 of the second storage bit 31 is coupled to the second interconnection node 33, and the source 313 of the second storage bit 31 is coupled to a programming voltage V_{PR2}. By default, the second storage bit 31 stores the disconnection information of the second interconnection node 33 therein, and the second interconnection node 33 is in a disconnected state. In addition, changers are accumulated on the floating gate 314 of the second storage bit 31 at this time. When the gate voltage V_{G2} is set to be a high electrical potential, for example 12 volt, and the programming voltage V_{PR2} is set to be a low electrical potential or a zero electrical potential, the changers accumulated on the floating gate 314 are able to be transferred and erased, thus the second interconnection node 33 is recorded as in a connected state. When the gate voltage V_{G2} is reset to be a low electrical potential, for example 1.5 volt, and the programming voltage V_{PR2} is reset to be a high electrical potential, loading a drop-down current (may be about 3.5 uA) to the second interconnection node 33, so that the changers on the floating gate 314 can be regained for rewriting data into the second storage bit 31. Accordingly, the second interconnection node 33 is recorded as in the disconnected state.

Regarding to the third interconnection node 42, connection or disconnection information of the third interconnection node 42 is stored by the first storage bit 40. Specifically, the control gate 401 of the first storage bit 40 is controlled by a gate voltage V_{G3}, the drain 402 of the first storage bit 40 is coupled to the third interconnection node 42, and the source 403 of the first storage bit 40 is coupled to a programming voltage V_{PR4}. By default, the first storage bit 40 stores the disconnection information of the third interconnection node 42 therein, and the third interconnection node 42 is in a disconnected state. In addition, changers are accumulated on the floating gate 404 of the first storage bit 40 at this time. When the gate voltage V_{G3} is set to be a high electrical potential, for example 12 volt, and the programming voltage V_{PR3} is set to be a low electrical potential or a zero electrical potential, the changers accumulated on the floating gate 404 are able to be transferred and erased, thus the third interconnection node 42 is recorded as in a connected state. When the gate voltage V_{G3} is reset to be a low electrical potential, for example 1.5 volt, and the programming voltage V_{PR3} is reset to be a high electrical potential, loading a drop-down current (may be about 3.5 μA) to the third interconnect node 42, so that the changers on the floating gate 404 can be regained for rewriting data into the first storage bit 40. Accordingly, the third interconnection node 42 is recorded as in the disconnected state again.

Regarding to the fourth interconnection node 43, connection or disconnection information of the fourth interconnection node 43 is stored by the second storage bit 41. Specifically, the control gate 411 of the second storage bit 41 is controlled by a gate voltage V_{G4}, the drain 412 of the second storage bit 41 is coupled to the fourth interconnection node 43, and the source 413 of the second storage bit 41 is coupled to a programming voltage V_{PR4}. By default, the second storage bit 41 stores the disconnection information of the fourth interconnect node 43 therein, and the fourth interconnection node 43 is in a disconnected state. In addition, changers are accumulated on the floating gate 414 of the second storage bit 41 at this time. When the gate voltage V_{G4} is set to be a high electrical potential, for example 12 volt, and the programming voltage V_{PR4} is set to be a low electrical potential or a zero electrical potential, the changers accumulated on the floating gate 414 are able to be transferred and erased, thus the fourth interconnection node 43 is recorded as in a connect state. When the gate voltage V_{G4} is reset to be a low electrical potential, for example 1.5 volt, and the programming voltage V_{PR4} is reset to be a high electrical potential, loading a drop-down current (may be about 3.5 μA) to the fourth interconnection node 43, so that the changers on the floating gate 414 can be regained for rewriting data into the second storage bit 41. Accordingly, the fourth interconnection node 43 is recorded as in the disconnected state again.

As the first interconnection node 32, the second interconnection node 33 and the third interconnection node 42 have the interconnection relation, connection and disconnection information of the first interconnection node 32, the second interconnection node 33 and the third interconnection node 42 are consistent. Therefore, the gate voltage V_{G1} and the gate voltage V_{G3} are a same control signal, and the programming voltage V_{PR1} and the programming voltage V_{PR3} are a same control signal as well.

The fourth interconnection node 43 has no interconnection relation with any one of the first interconnection node 32, the second interconnection node 33 and the third interconnection node 42, thus gate voltage V_{G4} and the programming voltage V_{PR4} are separately provided and are independent control signals.

Referring still to FIG. 4, the programming voltage V_{PR1} (V_{PR2} or V_{PR3}) can be controlled by a transistor 34. The transistor 34 may be a PMOS transistor as well, which has a source coupled to a programming high voltage V_{PHV1}, a drain coupled to the shared source 303/313 of the first storage bit 30 and the second storage bit 31, and a gate coupled to a programming control signal P_{EN1}. The programming control signal P_{EN1} is in a high level when a programming (for example, writing in the charges on the floating gate) is implemented to the storage bit. Otherwise, the programming control signal P_{EN1} is in a low level. Given that the first storage bit 40 and the second storage bit 41 have a shared source, the programming voltage V_{PR4} of the second storage bit 41 is able to be provided by the transistor 34 as well, but the gate voltage V_{G4} and the gate voltage V_{G1} are provided independently.

Although the present disclosure has been disclosed above with reference to preferred embodiments thereof, it should be understood by those skilled in the art that various changes may be made without departing from the spirit or scope of the disclosure. Accordingly, the present disclosure is not limited to the embodiments disclose.

What is claimed is:

1. A field programmable gate array, comprising:
a split gate memory;
a programmable logic unit; and
a wiring structure of the programmable logic unit;
wherein the wiring structure comprises interconnection nodes located on connection points thereof, and the split gate memory is adapted to provide an interconnection relation between the interconnect nodes.

2. The field programmable gate array according to claim 1, wherein the split gate memory comprises:
a first split gate storage array adapted to store content implemented by the programmable logic unit; and a second split gate storage array adapted to connect the interconnection nodes.

3. The field programmable gate array according to claim 2, wherein the interconnection nodes comprise:
a first interconnection node and a second interconnection node having the interconnection relation with each other;
wherein the second split gate storage array includes a first split gate storage bit and a second split gate storage bit each of which comprises a bit line electrode, a control gate and a source line electrode;
wherein the bit line electrode of the first split gate storage bit is coupled to the first interconnection node, the control gate of the first split gate storage bit is coupled to a gate control voltage, and the source line electrode of the first split gate storage bit is adapted to be coupled to a programming voltage when the first interconnection node and the second interconnection node are interconnected; and
wherein the bit line electrode of the second split gate storage bit is coupled to the second interconnection node, the control gate of the second split gate storage bit is coupled to the gate control voltage, and the source line electrode of the second split gate storage bit is adapted to be coupled to the programming voltage when the first interconnection node and the second interconnection node are interconnected.

4. The field programmable gate array according to claim 3, wherein the first split gate storage bit and the second split gate storage bit used a common source line electrode.

5. The field programmable gate array according to claim 3, further comprising a control transistor, wherein the control transistor has one end coupled to a control voltage, another end coupled to the source line electrodes of the first split gate storage bit and the second split gate storage bit, and a control end coupled to an enable signal, wherein the enable signal works when the first interconnection node and the second interconnection node are interconnected.

6. A switch structure for a FPGA which comprises a programmable logic unit and a wiring structure having interconnection nodes at connection points thereof, comprising: a split gate memory adapted to provide an interconnection relation between the interconnection nodes.

7. The switch structure according to claim 6, wherein the split gate memory comprises: a first split gate storage array adapted to store content implemented by the programmable logic unit; and a second split gate storage array adapted to connect the interconnection nodes.

8. The switch structure according to claim 7, wherein the interconnection nodes comprise: a first interconnection node and a second interconnection node having the interconnection relation with each other;
wherein the second split gate storage array comprises a first split gate storage bit and a second split gate storage bit each of which comprises a bit line electrode, a control gate and a source line electrode;
wherein the bit line electrode of the first split gate storage bit is coupled to the first interconnection node, the control gate of the first split gate storage bit is coupled to a gate control voltage, and the source line electrode of the first split gate storage bit is adapted to be coupled to a programming voltage when the first interconnection node and the second interconnection node are interconnected; and
wherein the bit line electrode of the second split gate storage bit is coupled to the second interconnection node, the control gate of the second split gate storage bit is coupled to the gate-control voltage, and the source line electrode of the second split gate storage bit is adapted to be coupled to the programming voltage when the first interconnection node and the second interconnection node are interconnected.

9. The switch structure according to claim 8, wherein the first split gate storage bit and the second split gate storage bit use a common source line electrode.
